(19) United States
(12) Patent Application Publication
(10) Pub. No.: US 2026/0033383 A1
(43) Pub. Date: Jan. 29, 2026

(54) POLYMER MATERIAL GAP-FILL FOR HYBRID BONDING IN A STACKED SEMICONDUCTOR SYSTEM

(71) Applicant: Micron Technology, Inc., Boise, ID (US)

(72) Inventor: Wei Zhou, Boise, ID (US)

(21) Appl. No.: 19/270,286

(22) Filed: Jul. 15, 2025

Related U.S. Application Data
(60) Provisional application No. 63/674,703, filed on Jul. 23, 2024.

(51) Int. Cl. H01L 23/29; H01L 21/48; H01L 21/56; H01L 23/00; H01L 23/31; H01L 23/48; H01L 25/18; H10B 80/00; H10D 80/30

(52) U.S. Cl. CPC H01L 23/291; H01L 21/486; H01L 21/56; H01L 23/3121; H01L 23/3185; H01L 24/05; H01L 24/08; H01L 24/80; H01L 25/18; H01L 23/481; H01L 2224/05187; H01L 2224/08146; H01L 2224/08225; H01L 2224/80895; H01L 2224/80896; H01L 2225/06524; H01L 2225/06541; H01L 2225/06548; H01L 2924/1431; H01L 2924/14361; H10B 80/00; H10D 80/30

(57) ABSTRACT

Methods, systems, and devices for polymer material gap-fill for hybrid bonding in a stacked semiconductor system are described. A stacked semiconductor may include a first semiconductor die on a semiconductor wafer. A polymer material may be on the semiconductor wafer and may at least partially surround the first semiconductor die. A silicon nitride material may be on the first semiconductor die and on the polymer material. And a second semiconductor die may be hybrid bonded with a bonding material on the silicon nitride material.

### CROSS REFERENCE

The present application for patent claims priority to U.S. Provisional Patent Application No. 63/674,703 by Zhou, entitled “POLYMER MATERIAL GAP-FILL FOR HYBRID BONDING IN A STACKED SEMICONDUCTOR SYSTEM,” filed Jul. 23, 2024, which is assigned to the assignee hereof, and which is expressly incorporated by reference in its entirety herein.

### TECHNICAL FIELD

The following relates to one or more semiconductor systems including a stacked semiconductor system with a polymer material gap-fill for hybrid bonding.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports polymer material gap-fill for hybrid bonding in a stacked semiconductor system in accordance with examples as disclosed herein.

FIG. 2 shows an example of a system that supports polymer material gap-fill for hybrid bonding in a stacked semiconductor system in accordance with examples as disclosed herein.

FIGS. 3A through 3G show examples of a stacked semiconductor system at various steps of a manufacturing process that supports a polymer material gap-fill for hybrid bonding in accordance with examples as disclosed herein.

FIG. 4 shows a flowchart illustrating a method or methods that support a polymer material gap-fill for hybrid bonding in a stacked semiconductor system in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

During manufacturing of a stacked architecture, also referred to as a stacked semiconductor system, it may be advantageous to use hybrid bonding to couple the semiconductor dies in a stacked formation (e.g., one above the other). To do so, a bonding material (e.g., silicon dioxide (SiO2)) that supports hybrid bonding may be deposited over a layer of dies so that the gaps between the dies are filled. The bonding material may then be ground down to expose the dies for hybrid bonding. But depositing the bonding material to fill in the gaps may be a slow process that increases in latency with the depth of the gaps (thus increasing manufacturing time), and grinding the bonding material may damage the dies and leave the bonding material with a rough surface that decreases the integrity of the hybrid bond.

According to the designs and techniques described herein, a gap-fill material such as a polymer material may be used to fill the gaps between dies. The polymer material may support a faster deposition process relative to the bonding material and may be ground down without damaging the dies. However, the polymer may not be suitable for hybrid bonding. Accordingly, an intermediate material, such as a silicon nitride (SiN) material, may be deposited on the polymer material so that a bonding material appropriate for hybrid bonding can be deposited thereupon. Hybrid bonding may then be used to couple the bottom dies with corresponding upper dies.

In addition to applicability in memory systems as described herein, techniques for stacked semiconductor systems with polymer material gap-fills may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and eliminating production processes, which may result in lowered production emissions and reduce electronic waste, among other benefits.

In addition to applicability in memory systems as described herein, techniques for stacked semiconductor systems with polymer material gap-fills may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving the coupling and electrical connections between semiconductor dies, among other benefits.

Features of the disclosure are illustrated and described in the context of systems and architectures. Features of the disclosure are further illustrated and described in the context of a flowchart.

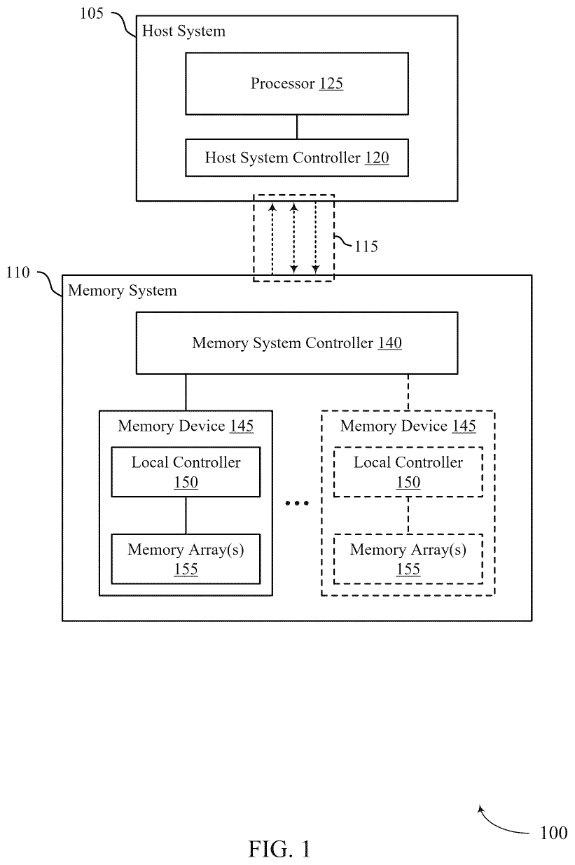

FIG. 1 shows an example of a system 100 that supports polymer material gap-fill for hybrid bonding in a stacked semiconductor system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture, also referred to as a stacked semiconductor system, in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

To form a stacked semiconductor system, a first (e.g., bottom) set of dies may be coupled with a base wafer, such as a logic wafer. To fill in the gaps between the dies, the set of dies may be covered with a bonding material that supports hybrid bonding. However, as part of the deposition process the bonding material may also be deposited on the dies. To expose the dies for hybrid bonding, the bonding material may be ground down in a process that may damage the dies and that may leave an uneven surface for hybrid bonding, each of which may negatively impact the formation and/or function of the stacked semiconductor system.

According to the designs and techniques described herein, a gap-fill material (e.g., a polymer material) may be used to fill in the gaps between dies and an intermediate material (e.g., a SiN material) may be deposited on the gap-fill material. The intermediate material may serve as the base for a bonding material that supports hybrid bonding and that houses bonding pads for coupling the first set of dies with a second (e.g., upper) set of dies. So, unlike in other stacked semiconductor systems, the gap-fill material may be different than the bonding material. The bonding material may be the same material as the intermediate material (e.g., but deposited as two different layers) of the bonding material may be a different material (e.g., a silicon carbon nitride (SiCN) material). Thus, the intermediate material may be capable of adhering to both the gap-fill material and the bonding material. After deposition of the bonding material, the second set of dies may be coupled with the first set of dies via hybrid bonding.

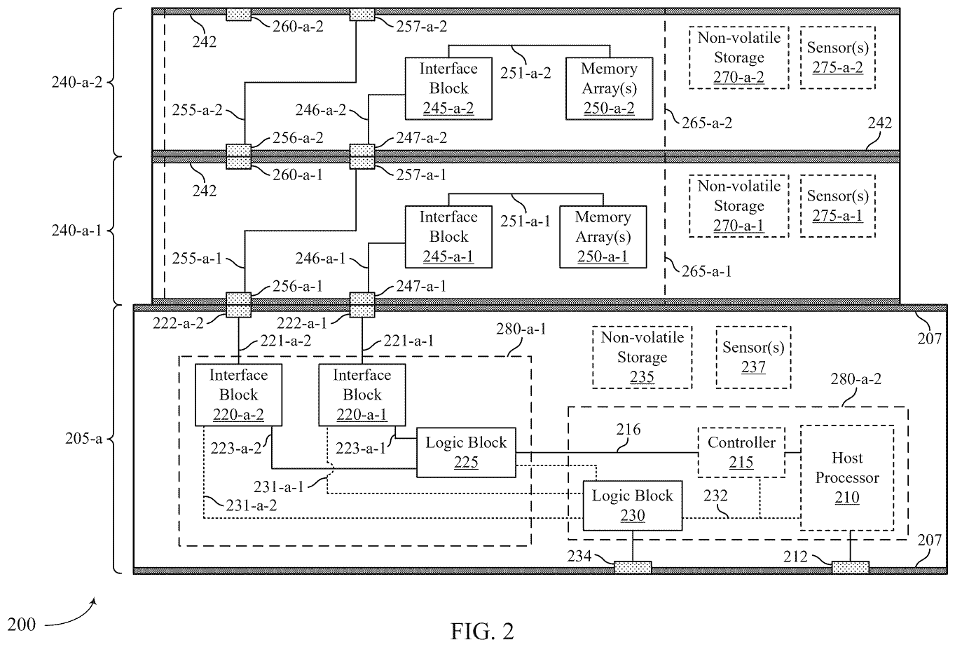

FIG. 2 shows an example of a system 200 (e.g., a semiconductor system, a system of coupled semiconductor dies, an HBM system, a 3D stacked memory system) that supports polymer material gap-fill for hybrid bonding in a stacked semiconductor system in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

According to the designs and techniques described herein, a gap-fill material (e.g., a polymer material) rather than a bonding material may be used to fill in the gaps between dies or to at least partially surround a die, such as the die 240-a-1. An intermediate material may be deposited on the gap-fill material to act as the base for a bonding material that supports hybrid bonding and that houses bonding pads (e.g., contacts 247) for coupling the die 240-a-1 to another die (e.g., die 240-a-2). After deposition of the bonding material, the die 240-a-2 may be coupled with the die 240-a-1 via hybrid bonding.

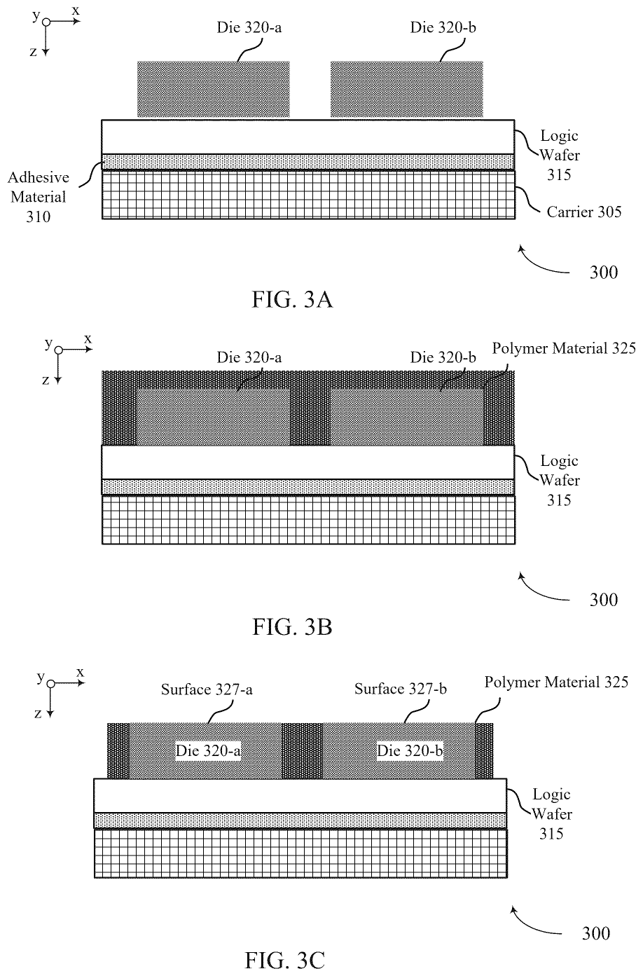

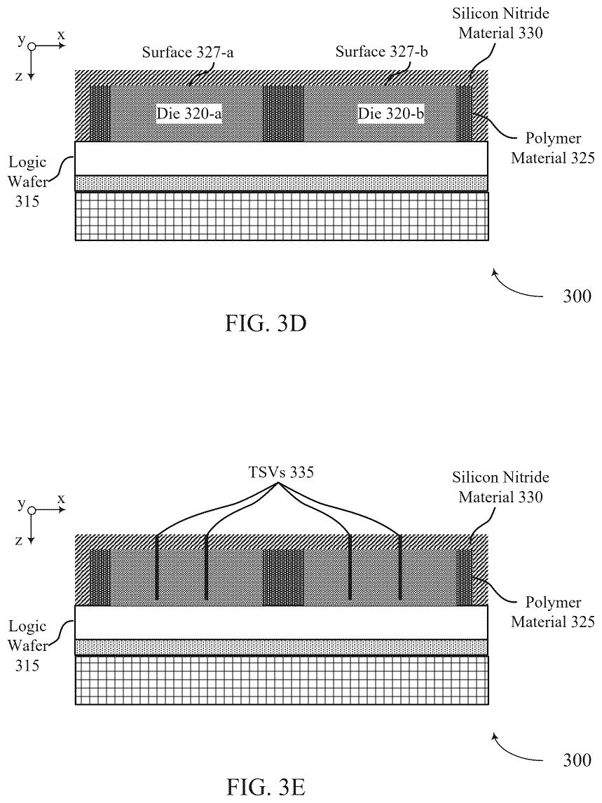

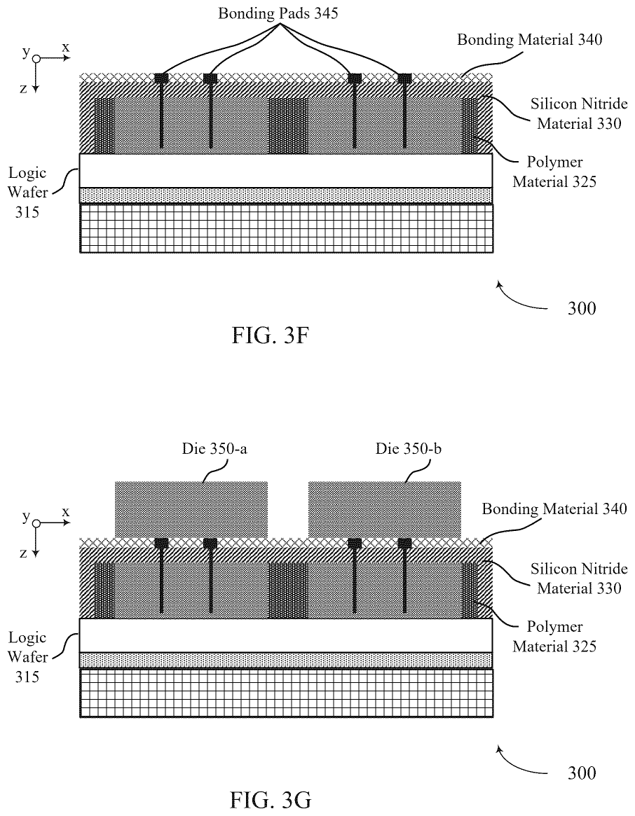

FIGS. 3A through 3G illustrate steps in a manufacturing process that produces a stacked semiconductor system 300 as described herein. Additional steps of the manufacturing may be added and one or more steps of the manufacturing process may be omitted or rearranged. During the manufacturing process, a gap-fill material (e.g., a polymer material 325) may be deposited to fill the gaps between dies of the stacked semiconductor system 300 and to act as a base for intermediate material (e.g., a silicon nitride material 330), which in turn may act as a base for a bonding material 340 that supports hybrid bonding and that includes bonding pads. The versions of the stacked semiconductor system 300 illustrated in FIGS. 3A through 3G may be understood in the context of the provided x-y-z coordinate system.

Although shown (in FIG. 3G) with reference to a 4:1 configuration where four dies are coupled with one logic wafer, the techniques described herein may be implemented in other configurations, such as 2:1 configuration, a 4:2 configuration, a 2:2 configuration, a 8:1 configuration, a 12:1 configuration, a 16:1 configuration and so on, where an n: N configuration refers to a configuration with n memory dies and N logic wafers. In some examples (e.g., in 3D stacked memory systems) there may be multiple (e.g., 4, 6, 8) n: N configuration stacks (e.g., 8:1 configuration, 12:1 configuration, 16:1 configuration) on a processor (e.g., a CPU, a GPU).

Although shown (in FIG. 3G) in an HBM configuration, with multiple dies stacked on the logic die, other types of configurations (e.g., homogeneous configurations that feature the same die-type, other heterogeneous configurations that feature a different combination of die-types) are contemplated and within the scope of the present disclosure. For example, the bottom die in FIG. 3G may be another memory die, one or more of the dies in FIG. 3G may be a logic die or memory die, etc.

FIG. 3A shows an example of the stacked semiconductor system 300 after a manufacturing step A of the manufacturing process. The stacked semiconductor system 300 may include a carrier 305 and a logic wafer 315 that is coupled with the carrier 305 via an adhesive material 310. Although described with reference to a logic wafer, the base wafer may be any type of wafer, including a memory wafer. A logic wafer may also be referred to as a logic die or other suitable terminology. The carrier 305 may be an example of wafer that provides mechanical support for the stacked semiconductor system 300 during at least a portion of a manufacturing process. The logic wafer 315 may be an example of a host system 105 as described with reference to FIG. 1 or the logic wafer may be an example of a die 205 (e.g., a logic die, a processor die, a host die, a logic unit) as described with reference to FIG. 2.

The manufacturing process may include depositing the die 320-a and the die 320-b on the logic wafer 315 so that the die 320-a and the die 320-b are coupled with the logic wafer 315. For example, bottom surfaces of the dies 320 may be coupled with a top surface of the logic wafer 315. So, after manufacturing step A, die 320-a may be deposited on, and coupled with, the logic wafer 315. And die 320-b may be deposited on, and coupled with, the logic wafer 315. The dies 320 may be memory dies, logic dies, or other types of semiconductor dies. Although shown with two dies 320 the stacked semiconductor system 300 may include any quantity of dies 320 (e.g., one die, three dies, n dies, where n is a positive integer).

FIG. 3B shows an example of the stacked semiconductor system 300 after a manufacturing step B of the manufacturing process. The manufacturing process may include depositing a gap-fill material, such as the polymer material 325, over (e.g., on) the dies 320, such that the polymer material 325 at least partially surrounds the dies 320. Thus, the polymer material 325 may be deposited over (e.g., on) the die 320-a and may be deposited over (e.g., on) the die 320-b. In some examples, deposition of the polymer material 325 may be referred to as polymer encapsulation. In some examples, the polymer material 325 may be in contact with (e.g., physically touching) the dies 320. The polymer material 325 may be deposited on the top surfaces of the dies 320 and may at least partially surround one or more lateral sides of the dies 320. In some examples, the polymer material 325 may be in contact with (e.g., physically touching) the logic wafer 315.

So, after manufacturing step B, the polymer material 325 may at least partially surround the dies 320. In some examples, the polymer material 325 may be an epoxy mold compound (EMC). In some examples, depositing the polymer material 325 may be referred to as polymer encapsulation.

FIG. 3C shows an example of the stacked semiconductor system 300 after a manufacturing step C of the manufacturing process. The manufacturing process may include a removal process (e.g., a grinding process) (also referred to as a planarization process) to remove some of (e.g., a portion of) the polymer material 325 so that the surfaces 327 of the dies 320 are exposed (e.g., for a subsequent bonding process). For example, removal of some of the polymer material 325 may expose the surface 327-a of the die 320-a and may expose the surface 327-b (e.g., the top surface) of the die 320-b. So, after manufacturing step C, the surfaces 327 of the dies 320 may be exposed and a top surface of the polymer material 325 may be substantially flush with the surfaces 327. In some examples, the removal process may also shave down the lateral sides of the polymer material 325. Removal of the polymer material 325 may be easier than removal of a bonding material and may result in less damage to the dies 320 relative to techniques that use a bonding material over the dies 320.

FIG. 3D shows an example of the stacked semiconductor system 300 after a manufacturing step D of the manufacturing process. The manufacturing process may include depositing an intermediate material, such as the silicon nitride material 330, over (e.g., on) the polymer material 325 and the dies 320. The silicon nitride material 330 may be deposited such that the silicon nitride material 330 covers (e.g., is in contact with) the polymer material 325 and the surfaces 327 of the dies 320. The silicon nitride material 330 may be capable of adhering to both the polymer material 325 and a bonding material used later in the manufacturing process and thus may serve as an intermediate or tie layer between the polymer material 325 and the bonding material. So, after manufacturing step D, the silicon nitride material 330 may extend over the dies 320 and the polymer material 325.

FIG. 3E shows an example of the stacked semiconductor system 300 after a manufacturing step E of the manufacturing process. The manufacturing process may include forming one or more vias (e.g., through-silicon-vias (TSVs) 335) through the silicon nitride material 330, the polymer material 325, and the dies 320. The TSVs 335 may enable the transfer of power and/or the communication of information between the dies 320 and additional dies that are disposed on top of the dies 320 in a later manufacturing step. So, after manufacturing step E, the TSVs 335 may extend at least partially through the silicon nitride material 330, the polymer material 325, and the dies 320.

FIG. 3F shows an example of the stacked semiconductor system 300 after a manufacturing step F of the manufacturing process. The manufacturing process may include deposition of a bonding material 340 over (e.g., on) the silicon nitride material 330 and the formation of bonding pads 345 (e.g., conductive pads such as copper (Cu) pads) in contact with the TSVs 335. In some examples, the bonding pads 345 may be formed before deposition of the bonding material 340. In other examples, the bonding pads 345 may be formed after deposition of the bonding material 340. In either event, the bonding pads 345 may be disposed within the bonding material 340 and may be coupled with the TSVs 335.

In some examples, the bonding material 340 may be the same silicon nitride material as the silicon nitride material 330. For instance, the silicon nitride material 330 deposited during step D may be a first layer of silicon nitride material and the bonding material 340 deposited during step F may be a second layer of the silicon nitride material. In other examples, the bonding material 340 may be a silicon carbon nitride (SiCN) material. So, the bonding material 340 may support hybrid bonding and may adhere to the silicon nitride material 330. In addition to supporting hybrid bonding, the bonding material 340 may house the bonding pads 345. Other materials suitable for hybrid bonding are contemplated for the bonding material 340 and are within the scope of the present disclosure.

So, after manufacturing step F, the bonding material 340 may be deposited over the silicon nitride material 330 and the bonding pads 345 may be deposited within the bonding material 340 (and coupled with the TSVs 335). Accordingly, the stacked semiconductor system 300 may be ready for hybrid bonding with another set of dies.

FIG. 3G shows an example of the stacked semiconductor system 300 after a manufacturing step G of the manufacturing process. The manufacturing process may include hybrid bonding between the dies 350 (e.g., die 350-a, die 350-b) and the bonding material 340. Accordingly, the dies 350 may be coupled with the bonding pads 345 embedded within the bonding material 340 (e.g., so that power signals and/or communication signals can be transferred between the dies 350 and the dies 320). Thus, the dies 350 may be coupled with the dies 320 through the bonding pads 345 and the TSVs 335, which may extend at least partially through the silicon nitride material 330, the polymer material 325, and the dies 320.

So, after manufacturing step G, the dies 350 may be coupled with the bonding material 340 via a hybrid bond. Die 350-a may be above (and coupled with die 320-a), whereas die 350-b may be above (and coupled with) die 320-b. In some examples, the manufacturing steps 3A through 3G may be repeated for additional layers of dies.

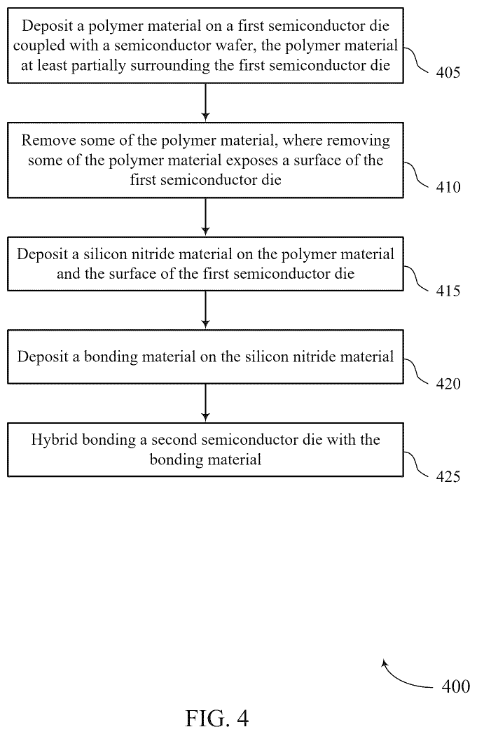

FIG. 4 shows a flowchart illustrating a method 400 that supports polymer material gap-fill for hybrid bonding in a stacked semiconductor system in accordance with examples as disclosed herein. The operations of method 400 may be implemented by a manufacturing system or its components as described herein. For example, the operations of method 400 may be performed by a manufacturing system. In some examples, a manufacturing system may execute a set of instructions to control the functional elements of the device to perform the described functions. Additionally, or alternatively, the manufacturing system may perform aspects of the described functions using special-purpose hardware.

At 405, the method may include depositing a polymer material on a first semiconductor die coupled with a semiconductor wafer, the polymer material at least partially surrounding the first semiconductor die. In some examples, aspects of the operations of 405 may be performed by a manufacturing system.

At 410, the method may include removing some of the polymer material, where removing some of the polymer material exposes a surface of the first semiconductor die. In some examples, aspects of the operations of 410 may be performed by a manufacturing system.

At 415, the method may include depositing a silicon nitride material on the polymer material and the surface of the first semiconductor die. In some examples, aspects of the operations of 415 may be performed by a manufacturing system.

At 420, the method may include depositing a bonding material on the silicon nitride material. In some examples, aspects of the operations of 420 may be performed by a manufacturing system.

At 425, the method may include hybrid bonding a second semiconductor die with the bonding material. In some examples, aspects of the operations of 425 may be performed by a manufacturing system.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for depositing a polymer material on a first semiconductor die coupled with a semiconductor wafer, the polymer material at least partially surrounding the first semiconductor die; removing some of the polymer material, where removing some of the polymer material exposes a surface of the first semiconductor die; depositing a silicon nitride material on the polymer material and the surface of the first semiconductor die; depositing a bonding material on the silicon nitride material; and hybrid bonding a second semiconductor die with the bonding material.

Aspect 2: The method, apparatus, or non-transitory computer-readable medium of aspect 1, further including operations, features, circuitry, logic, means, or instructions, or any combination thereof for forming, based at least in part on depositing the silicon nitride material, a through-silicon-via (TSV) that extends at least partially through the silicon nitride material and the first semiconductor die.

Aspect 3: The method, apparatus, or non-transitory computer-readable medium of aspect 2, further including operations, features, circuitry, logic, means, or instructions, or any combination thereof for forming a bonding pad that is within the bonding material and that is coupled with the TSV, where the second semiconductor die is coupled with the bonding pad after hybrid bonding the second semiconductor die with the bonding material.

Aspect 4: The method, apparatus, or non-transitory computer-readable medium of any of aspects 1 through 3, where the polymer material at least partially fills a cavity between the first semiconductor die and a third semiconductor die on the semiconductor wafer.

Aspect 5: The method, apparatus, or non-transitory computer-readable medium of aspect 4, where removing some of the polymer material exposes a surface of the third semiconductor die and silicon nitride material is deposited on the surface of the third semiconductor die.

Aspect 6: The method, apparatus, or non-transitory computer-readable medium of aspect 5, further including operations, features, circuitry, logic, means, or instructions, or any combination thereof for hybrid bonding a fourth semiconductor die with the bonding material, where the fourth semiconductor die is coupled with the third semiconductor die by a through-silicon-via (TSV) that extends at least partially through the silicon nitride material and the polymer material.

Aspect 7: The method, apparatus, or non-transitory computer-readable medium of any of aspects 1 through 6, where the silicon nitride material includes a first layer of silicon nitride material and the bonding material includes a second layer of silicon nitride material.

Aspect 8: The method, apparatus, or non-transitory computer-readable medium of any of aspects 1 through 7, where the bonding material includes a silicon carbon nitride (SiCN) material.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a first semiconductor die on a semiconductor wafer; a polymer material on the semiconductor wafer and at least partially surrounding the first semiconductor die; a silicon nitride material on the first semiconductor die and on the polymer material; and a second semiconductor die hybrid bonded with a bonding material on the silicon nitride material.

Aspect 10: The apparatus of aspect 9, further including: a third semiconductor die on the semiconductor wafer, where the polymer material is between the first semiconductor die and the third semiconductor die.

Aspect 11: The apparatus of aspect 10, where the silicon nitride material is on the third semiconductor die, and the bonding material on the silicon nitride material extends over the third semiconductor die.

Aspect 12: The apparatus of aspect 11, further including: a through-silicon-via (TSV) that extends at least partially through the silicon nitride material and the third semiconductor die.

Aspect 13: The apparatus of aspect 12, further including: a bonding pad at least partially within the bonding material and coupled with the TSV and a fourth semiconductor die that is hybrid bonded with the bonding material on the silicon nitride material.

Aspect 14: The apparatus of any of aspects 9 through 13, further including: a through-silicon-via (TSV) that extends at least partially through the silicon nitride material and the first semiconductor die.

Aspect 15: The apparatus of aspect 14, further including: a bonding pad at least partially within the bonding material and coupled with the TSV and the second semiconductor die.

Aspect 16: The apparatus of any of aspects 9 through 15, where the silicon nitride material includes a first layer of silicon nitride material, and the bonding material includes a second layer of silicon nitride material.

Aspect 17: The apparatus of any of aspects 9 through 16, where the bonding material includes a silicon carbon nitride (SiCN) material.

An apparatus is described. The following provides an overview of aspects of the apparatus as described herein:

Aspect 18: An apparatus, including: a first semiconductor die on a semiconductor wafer, a bottom surface of the first semiconductor die coupled with a top surface of the semiconductor wafer; a polymer material on the top surface of the semiconductor wafer and at least partially surrounding a lateral side of the first semiconductor die, a top surface of the polymer material flush with a top surface of the first semiconductor die; a silicon nitride material on the top surface of the first semiconductor die and on the top surface of the polymer material; and a second semiconductor die hybrid bonded with a bonding material on the silicon nitride material.

Aspect 19: The apparatus of aspect 18, further including: a third semiconductor die on the semiconductor wafer and coupled with the top surface of the semiconductor wafer, where the polymer material at least partially surrounds a lateral surface of the third semiconductor die and is between the first semiconductor die and the third semiconductor die.

Aspect 20: The apparatus of aspect 19, where the silicon nitride material is on a top surface of the third semiconductor die, and the bonding material on the silicon nitride material extends over the third semiconductor die.

Aspect 21: The apparatus of aspect 20, further including: a through-silicon-via (TSV) that extends at least partially through the silicon nitride material and the third semiconductor die.

Aspect 22: The apparatus of aspect 21, further including: a bonding pad at least partially within the bonding material and coupled with the TSV and a fourth semiconductor die that is hybrid bonded with the bonding material on the silicon nitride material.

Aspect 23: The apparatus of any of aspects 18 through 22, further including: a through-silicon-via (TSV) that extends at least partially through the silicon nitride material and the top surface of the first semiconductor die.

Aspect 24: The apparatus of aspect 23, further including: a bonding pad at least partially within the bonding material and coupled with the TSV and the second semiconductor die.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first semiconductor die on a semiconductor wafer;
a polymer material on the semiconductor wafer and at least partially surrounding the first semiconductor die;
a silicon nitride material on the first semiconductor die and on the polymer material; and
a second semiconductor die hybrid bonded with a bonding material on the silicon nitride material.

2. The apparatus of claim 1, further comprising:
a third semiconductor die on the semiconductor wafer, wherein the polymer material is between the first semiconductor die and the third semiconductor die.

3. The apparatus of claim 2, wherein the silicon nitride material is on the third semiconductor die, and wherein the bonding material on the silicon nitride material extends over the third semiconductor die.

4. The apparatus of claim 3, further comprising:
a through-silicon-via (TSV) that extends at least partially through the silicon nitride material and the third semiconductor die.

5. The apparatus of claim 4, further comprising:
a bonding pad at least partially within the bonding material and coupled with the TSV and a fourth semiconductor die that is hybrid bonded with the bonding material on the silicon nitride material.

6. The apparatus of claim 1, further comprising:
a through-silicon-via (TSV) that extends at least partially through the silicon nitride material and the first semiconductor die.

7. The apparatus of claim 6, further comprising:
a bonding pad at least partially within the bonding material and coupled with the TSV and the first semiconductor die.

8. The apparatus of claim 1, wherein the silicon nitride material comprises a first layer of silicon nitride material, and wherein the bonding material comprises a second layer of silicon nitride material.

9. The apparatus of claim 1, wherein the bonding material comprises a silicon carbon nitride (SiCN) material.

10. A method of manufacturing an apparatus, comprising:
depositing a polymer material on a first semiconductor die coupled with a semiconductor wafer, the polymer material at least partially surrounding the first semiconductor die;
removing some of the polymer material, wherein removing some of the polymer material exposes a surface of the first semiconductor die;
depositing a silicon nitride material on the polymer material and the surface of the first semiconductor die;
depositing a bonding material on the silicon nitride material; and
hybrid bonding a second semiconductor die with the bonding material.

11. The method of claim 10, further comprising:
forming, based at least in part on depositing the silicon nitride material, a through-silicon-via (TSV) that extends at least partially through the silicon nitride material and the first semiconductor die.

12. The method of claim 11, further comprising:
forming a bonding pad that is within the bonding material and that is coupled with the TSV, wherein the second semiconductor die is coupled with the bonding pad after hybrid bonding the second semiconductor die with the bonding material.

13. The method of claim 10, wherein the polymer material at least partially fills a cavity between the first semiconductor die and a third semiconductor die on the semiconductor wafer.

14. The method of claim 13, wherein removing some of the polymer material exposes a surface of the third semiconductor die, and wherein the silicon nitride material is deposited on the surface of the third semiconductor die.

15. The method of claim 14, further comprising:
hybrid bonding a fourth semiconductor die with the bonding material, wherein the fourth semiconductor die is coupled with the third semiconductor die by a through-silicon-via (TSV) that extends at least partially through the silicon nitride material and the polymer material.

16. The method of claim 10, wherein the silicon nitride material comprises a first layer of silicon nitride material, and wherein the bonding material comprises a second layer of silicon nitride material.

17. The method of claim 10, wherein the bonding material comprises a silicon carbon nitride (SiCN) material.

18. An apparatus, comprising:
a first semiconductor die on a semiconductor wafer, a bottom surface of the first semiconductor die coupled with a top surface of the semiconductor wafer;
a polymer material on the top surface of the semiconductor wafer and at least partially surrounding a lateral side of the first semiconductor die, a top surface of the polymer material flush with a top surface of the first semiconductor die;
a silicon nitride material on the top surface of the first semiconductor die and on the top surface of the polymer material; and
a second semiconductor die hybrid bonded with a bonding material on the silicon nitride material.

19. The apparatus of claim 18, further comprising:
a third semiconductor die on the semiconductor wafer and coupled with the top surface of the semiconductor wafer, wherein the polymer material at least partially surrounds a lateral surface of the third semiconductor die and is between the first semiconductor die and the third semiconductor die.

20. The apparatus of claim 19, wherein the silicon nitride material is on a top surface of the third semiconductor die, and wherein the bonding material on the silicon nitride material extends over the third semiconductor die.

21. The apparatus of claim 20, further comprising:
a through-silicon-via (TSV) that extends at least partially through the silicon nitride material and the third semiconductor die.

22. The apparatus of claim 21, further comprising:
a bonding pad at least partially within the bonding material and coupled with the TSV and a fourth semiconductor die that is hybrid bonded with the bonding material on the silicon nitride material.

23. The apparatus of claim 18, further comprising:
a through-silicon-via (TSV) that extends at least partially through the silicon nitride material and the top surface of the first semiconductor die.

24. The apparatus of claim 23, further comprising:
a bonding pad at least partially within the bonding material and coupled with the TSV and the first semiconductor die.
